(19) United States
(12) Patent Application Publication
(10) Pub. No.: US 2007/0284576 A1
(43) Pub. Date: Dec. 13, 2007

(54) SEMICONDUCTOR CIRCUIT ARRANGEMENT AND ASSOCIATED METHOD FOR TEMPERATURE DETECTION

(75) Inventors: Christian Pacha, Muenchen (DE); Thomas Schulz, Heverlee (BE); Klaus Von Arnim, Herzhorn (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/689,886

(22) Filed: Mar. 22, 2007

(30) Foreign Application Priority Data
Mar. 24, 2006 (DE) 10 2006 013 721.3

(51) Int. Cl. H01L 25/07; H01L 21/66

(52) U.S. Cl. 257/48; 438/18; 257/E25.016; 257/E21.522; 257/E21.525; 257/E21.53

(57) ABSTRACT

A semiconductor circuit arrangement and a method for temperature detection is disclosed. One embodiment includes a semiconductor substrate, on which is formed a first insulating layer and thereon a thin active semiconductor region, which is laterally delimited by a second insulating layer. In the active semiconductor region, a first and second doping zone are formed on the surface of the first insulating layer for the definition of a channel zone, wherein there is formed at the surface of the channel zone a gate dielectric and thereon a control electrode for the realization of a field effect transistor. In the active semiconductor region, a diode doping zone is formed on the surface of the first insulating layer, which zone realizes a measuring diode via a diode side area with the first or second doping zone and is delimited by the second insulating layer at its further side areas.

### CROSS-REFERENCE TO RELATED APPLICATIONS

This Utility Patent Application claims priority to German Patent Application No. DE 10 2006 013 721.3 filed on Mar. 24, 2007, which is incorporated herein by reference.

### BACKGROUND

The present invention relates to a semiconductor circuit arrangement and an associated method for temperature detection, and in particular to an analog SOI semiconductor circuit arrangement including multi-gate field effect transistors and also an associated method for temperature detection for e.g., an automatic temperature compensation.

Novel transistor architectures on the basis of multi-gate field effect transistors (MuGFETs) are currently being developed for future sub-45-nanometer CMOS technologies, that is to say for field effect transistors having a gate length of less than 45 nanometers. Multi-gate field effect transistors are usually understood to be field effect transistors having a multiplicity of gates or control electrodes, which also include transistors such as e.g., double-gate FETs, triple-gate FETs or FinFETs. The advantage of these new transistors over planar bulk MOSFETs, that is to say field effect transistors which are situated in planar fashion in a large-volume semiconductor substrate (bulk), is an improved control of the short channel effects by use of a symmetrical arrangement of a plurality of transistor gates.

The arrangement that is technologically favored at the present time includes two lateral gates, such as are known for example from FinFETs, or two lateral gates and one additional gate on the surface of a silicon fin, such as are also known as triple-gate FETs. The semiconductor or silicon fin is also referred to as a lamella in this case.

Planar SOI technologies with partially depleted channel regions (PD-SOI) are already used nowadays. Planar SOI technologies having a fully depleted channel region (FD-SOI) are additionally conceivable in the future.

What is disadvantageous about all transistor architectures of this type, however, is their inadequate thermal behavior. On account of the three-dimensional topology of the field effect transistors and on account of the fact that the fins are usually surrounded on all sides by oxide that conducts heat poorly, the power loss arising in the fins cannot be dissipated as efficiently as in conventional bulk transistors, for example.

For analog applications, in particular, the problem therefore arises that on account of different temperatures of the fins, an increased mismatch caused by temperature differences occurs in the semiconductor circuit.

Conventional semiconductor circuit arrangements and methods for temperature detection of the transistor usually require special test structures which, moreover, can only be characterized with high metrological outlay (RF measurements). Since very short current pulses are necessary in this case, radiofrequency structures are required. Measurement methods of this type are therefore very susceptible to interference and only indirectly yield information about the temperature within a transistor. What is more, a required measuring structure differs greatly from the respective arrangement in which a transistor is used later.

In particular, the multi-gate field effect transistors mentioned in the introduction are currently still in front-end development. Since it has not been possible hitherto for the temperature of such a transistor to be determined during the operation of a circuit, circuits have hitherto had to rely on a correct modeling of the thermal behavior. The thermal behavior is very different from transistor to transistor, however, on account of the process fluctuations and a different topology of the transistors.

### SUMMARY

A semiconductor circuit arrangement and a method for temperature detection is disclosed. One embodiment includes a semiconductor substrate, on which is formed a first insulating layer and thereon a thin active semiconductor region, which is laterally delimited by a second insulating layer. In the active semiconductor region, a first and second doping zone are formed as far as the surface of the first insulating layer for the definition of a channel zone, wherein there is formed at the surface of the channel zone a gate dielectric and thereon a control electrode for the realization of a field effect transistor. In the active semiconductor region, a diode doping zone is furthermore formed as far as the surface of the first insulating layer, which zone realizes a measuring diode via a diode side area with the first or second doping zone and is delimited by the second insulating layer at its further side areas. In this way, a highly accurate temperature detection can be realized very cost-effectively in a sub-45-nanometer field effect transistor.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A to 1C illustrate a simplified plan view, a sectional view and an equivalent circuit diagram of a semiconductor circuit arrangement in accordance with a first exemplary embodiment;

FIG. 2 illustrates a simplified sectional view of a semiconductor circuit arrangement with a P/N diode in accordance with a second exemplary embodiment;

FIG. 3 illustrates a simplified sectional view of a semiconductor circuit arrangement with a PiN diode in accordance with a third exemplary embodiment; FIGS. 4A and 4B illustrate a simplified plan view and a perspective partial view of a semiconductor circuit arrangement with a multi-gate field effect transistor in accordance with a fourth exemplary embodiment;

FIG. 5 illustrates a simplified plan view of a semiconductor circuit arrangement with a dummy control electrode in accordance with a fifth exemplary embodiment; and

FIG. 6 illustrates a simplified plan view of a semiconductor circuit arrangement with two measuring diodes in accordance with a sixth exemplary embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One aspect of the invention provides a semiconductor circuit arrangement which enables a simple, interference-immune and cost-effective temperature detection for a respective field effect transistor in a highly accurate manner.

In particular by virtue of the formation of at least one third diode doping zone in an active semiconductor region as far as a surface of a first insulating layer, which zone realizes a diode via a diode side area with the first or second doping zone of the field effect transistor and is delimited by the second insulating layer at its further side areas, it is possible to determine a temperature of a respective transistor highly accurately and in an extremely simple manner, whereby it is possible, by way of example, to realize an automatic temperature compensation in particular for analog circuits.

The third doping zone is formed directly alongside the first or second doping zone of the field effect transistor for the realization of a P/N diode, whereby it is possible to realize a temperature sensor with a minimal space requirement.

However, the third doping zone may also be formed in a manner spaced apart from the first or second doping zone by an intrinsic semiconductor region, whereby a PiN diode is produced and the electrical properties of the semiconductor circuit are improved further in the case of a sufficiently thin intrinsic semiconductor region and in the case of the diode being biased in the forward direction.

The field effect transistor constitutes a multi-gate field effect transistor having a multiplicity of fins in the region of the control layer, wherein the fins are laterally delimited by the second insulating layer. Short channel effects can thereby be avoided in particular for sub-45-nanometer field effect transistors.

In order to further improve the electrical properties of the semiconductor circuit arrangement and in particular in order to improve a contact-connection of the source and drain zones and of the diode, metal-semiconductor compound layers may be formed at the surface of the doping zones, a blocking layer for preventing a short circuit being formed only in the surface region of the diode side area.

As an alternative, instead of the blocking layer, it is possible to form a dummy gate dielectric with an overlying dummy control electrode over the diode side area, whereby a short circuit between a diode connection zone and a connection zone of the field effect transistor can be prevented once again and in a particularly cost-effective manner using the mask and etching processes present anyway for the formation of the control layer stack.

By way of example, a metallic mid-gap material, that is to say a material whose work function lies in the middle of the band gap of the semiconductor material of the active semiconductor region, is used for the control layer or the gate. The electrical properties of the semiconductor circuit arrangement can be improved further in this way.

Furthermore, a width of the fins may be significantly less than a gate length of the control electrode, whereby it is possible to ensure a good electrostatic control over the channel zones.

The second insulating layer may be formed by using STI technology as an STI layer or shallow trench isolation, whereby the very fine structures required can be formed particularly exactly and moreover cost-effectively.

With regard to the method, the diode of the semiconductor circuit arrangement described above is operated with a diode measuring current in the forward direction and the diode voltage dropped across the diode is subsequently measured. The ideal diode equation I=I₀ [exp(U_{DM}/U_{DT})−1] is simplified in the forward direction to I=I₀ ×exp(U_{DM}/U_{DT}), where U_{MD} represents the measured diode voltage and U_{T}=k_{B} T/q represents the voltage equivalent of thermal energy. By impressing a reference current I=I_{DD} into the diode, a diode voltage U_{MD} is present across the diode. A respective temperature of the transistor can then be detected by comparing the measured diode voltage with a reference voltage. The temperature dependence of the voltage can be estimated by the equation
U_{MD}=0.5 V−T×1.8 mV/K.

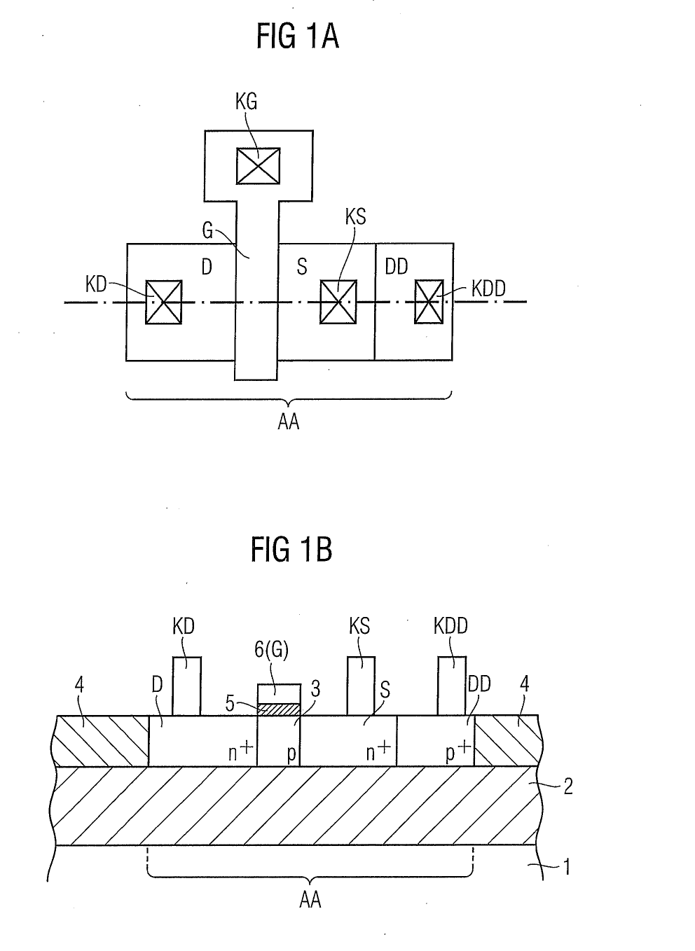

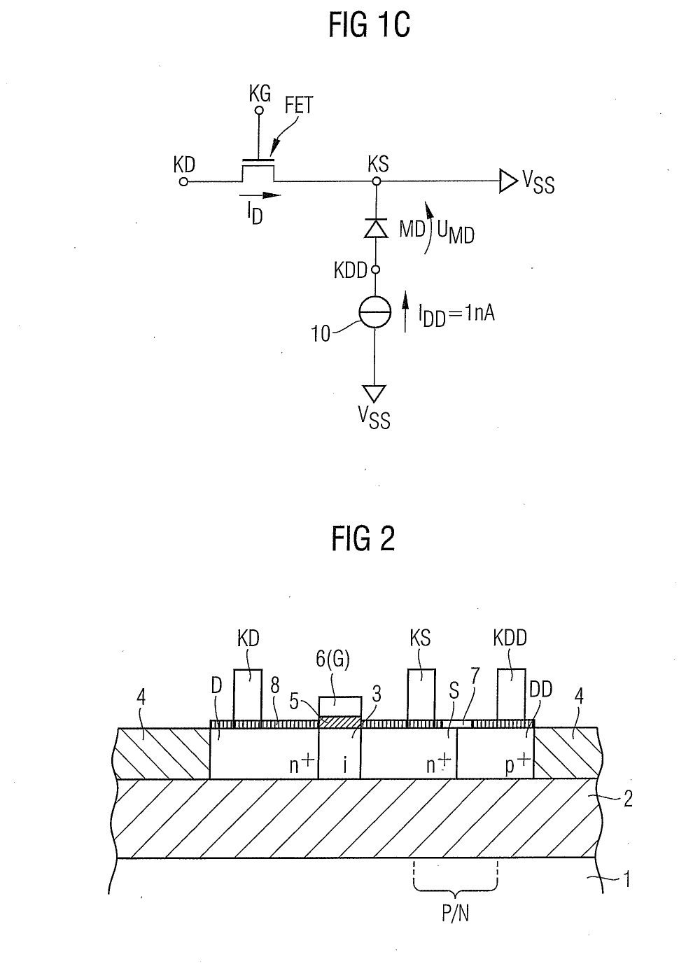

The diode measuring current is preferably less than 1/100 of the drain current of the field effect transistor, whereby a simultaneous temperature detection during normal operation of the field effect transistor can also be made possible FIGS. 1A to 1C respectively illustrate a simplified plan view and an associated sectional view and an associated equivalent circuit diagram of a semiconductor circuit arrangement in accordance with a first exemplary embodiment for the realization of a temperature detection.

In accordance with FIGS. 1A and 1B, the semiconductor circuit arrangement according to the invention is formed for example on a SOI substrate (Semiconductor-On-Insulator). In this case, a first insulating layer 2, which preferably constitutes silicon oxide or SiO₂, is formed on a semiconductor substrate 1, which constitutes a monocrystalline silicon substrate, for example. Firstly a thin semiconductor layer 3, which may be for example weakly p-doped, weakly n-doped or intrinsic (i) i.e. undoped, is situated at the surface of the first insulating layer 2.

The thin semiconductor layer 3 has monocrystalline silicon, for example, but it may also have other semiconductor materials such as e.g., III/V compound semiconductors and in particular strained semiconductor material (e.g., strained silicon). A height or thickness of the thin semiconductor layer 3 may be 60 nanometers, for example.

For the definition of active semiconductor regions AA, semiconductor regions that are not required in the thin semiconductor layer 3 are converted into insulation zones or a second insulating layer 4 for example by STI technology (Shallow Trench Isolation). By such STI technology, the STI layers 4 can be formed highly accurately for the definition of the active semiconductor regions AA, in which case they reach as far as the surface of the first insulating layer 2 of the carrier substrate.

Afterward, known methods are used to form, at the surface of the active semiconductor region AA, which is formed for example in rectangular fashion in accordance with FIG. 1A, a gate dielectric 5 and thereon a control layer 6 over the whole area. In order to realize the gate dielectric 5, an insulating layer composed of e.g., SiO₂ or high-k dielectrics may be formed over the whole area, for example, whereby the insulating layers required for the channel zones are obtained. In this case, high-k dielectrics are understood to be dielectric materials or insulating layers having an increased dielectric constant compared with the dielectric constant of silicon dioxide of k approximately 3.9, i.e. k greater than 4 to 20.

A highly doped polysilicon may preferably be used as material for the control layer 6 in a planar PD-SOI transistor. As an alternative to polysilicon, for FD-SOI transistors metallic materials whose work function lies in the vicinity of the middle of the band gap of silicon, mid-gap materials, e.g., TiN, TaN, TaCN, may be used for the control layer 6.

After the gate dielectric 5 and the control layer 6 have been formed preferably over the whole area, the control layer 6 is then patterned to form the control electrode G illustrated in FIG. 1A, in which case a control electrode G—overlapping the active semiconductor region AA—with an associated control electrode connection is formed by, for example, photolithographic methods and associated etching technology. The gate dielectric 5 may likewise be correspondingly patterned in this case.

In a subsequent process, the source and drain zones S and D may then be formed as first and second doping zones in the active semiconductor region AA using the control electrode G and a further mask layer that is optionally present (but not illustrated), in such a way that they extend completely as far as the surface of the first insulating layer 2. The channel zone of a field effect transistor to be realized is defined in this way.

In accordance with FIG. 1B, by way of example, a weakly p-doped active semiconductor region AA is n⁺-doped by use of ion implantation for the formation of the first and second doping zone or the source zone S and the drain zone D of the field effect transistor FET. A NMOS field effect transistor is produced in this way. It goes without saying that an n-doped active semiconductor region can also be doped in the same way with p⁺-type doping zones for the realization of the source and drain zones S and D.

Afterward, it is possible to remove the optional mask layer for covering the active semiconductor region for a diode doping zone DD and to form a further optional mask layer at the surface of the first and second doping zones or the source and drain zones S and D in order to protect them from a subsequent p⁺-type doping. In this way, the p⁺-type diode doping zone DD illustrated in FIG. 1B can be formed e.g., in a manner directly adjoining the source zone S of the field effect transistor.

It goes without saying that one of the optional masks may also be omitted, a corresponding implantation profile being created using mutually counterbalancing implantations, the doping zones for the source zone S, the drain zone D and the diode doping zone DD once again being formed in each case as far as the surface of the first insulating layer 2. In this way, the diode doping zone DD is doped with a conduction type p⁺ opposite to the conduction type n of the field effect transistor and forms a measuring diode with its diode side area, i.e. the area relevant to the diode junction, with the source or drain zone S, D. The further side areas of the diode doping zone DD are delimited by the second insulating layer or the STI layers.

For the contact-connection of the field effect transistor and the measuring diode MD, a drain contact KD, a source contact KS, a gate contact KG and a diode doping zone contact KDD are furthermore illustrated, which are formed e.g., at the surface of the respective zones or layers by conventional methods. These contacts are usually situated in a further intermediate insulating layer (not illustrated here) formed at the surface of the second insulating layer 4 and the active semiconductor regions AA.

FIG. 1C illustrates a simplified equivalent circuit diagram of the semiconductor circuit arrangement according to the invention, wherein identical reference symbols designate identical or corresponding elements, for which reason a repeated description is dispensed with below.

In order to realize a temperature detection, in accordance with FIG. 1C, a constant diode current I_{DD} is impressed on the measuring diode MD in the forward direction by a constant-current source 10. A diode voltage U_{MD} dropped across the measuring diode MD can then be measured between the source contact KS and the diode doping zone contact KDD, the diode voltage having a largely linear temperature dependence. Using a reference voltage (not illustrated), the measured diode voltage U_{MD} can subsequently be compared with the reference voltage and a temperature present in the transistor or in the active semiconductor region AA can thus be detected very accurately.

In order to simplify a circuit of this type, the use of the reference voltage (not illustrated) can also be omitted and the temperature of the transistor can be estimated from the equation:
U_{MD}=0.5 V−T×1.8 mV/K

where U_{MD} represents the measured diode voltage and T represents the temperature.

In this way, in particular for the field effect transistors produced in SOI substrates, a temperature detection can be realized in a highly accurate and very simple manner, whereby cost-effective temperature compensation circuits can be realized in particular for analog semiconductor circuits.

In particular when using a diode measuring current I_{DD} which is less than 1/100 of the drain current I_{D} present in the field effect transistor FET, it is furthermore possible to carry out a simultaneous temperature detection during normal operation of the transistor without adversely influencing the electrical properties of the field effect transistor FET in the process. Preferably, a diode measuring current I_{DD} of 1 nA is impressed on the measuring diode MD in the forward direction. The supply voltage of the semiconductor circuit is designated by Vₛₛ in accordance with FIG. 1C.

The semiconductor circuit illustrated in FIG. 1C can be connected externally (e.g., via a semiconductor pad) or else be realized as an integrated circuit in the same substrate. Care must merely be taken in this case to ensure that the diode MD and the constant-current source 10 do not influence the electrical behavior of the transistor.

Since the diode MD is situated in direct proximity to or in the same semiconductor region AA as the field effect transistor and the semiconductor material usually has an excellent thermal conductivity, the temperature of the respective transistor can be determined with extraordinarily high accuracy and with only a small additional space requirement. Given a multiplicity of field effect transistors formed in respective active semiconductor regions AA with associated measuring diodes MD, a respective temperature of the wide variety of transistors can thus be determined highly accurately even in a complex circuit. By suitable compensation circuits (not illustrated), it is thereby possible to compensate for e.g., the temperature-dictated mismatch between transistors in particular in an analog circuit.

FIG. 2 illustrates a simplified sectional view of a semiconductor circuit in accordance with a second exemplary embodiment, wherein identical reference symbols designate elements identical or corresponding to those in FIGS. 1A to 1C, for which reason a repeated description is dispensed with below.

In contrast to the first exemplary embodiment, in accordance with FIG. 2 the thin semiconductor layer 3 and the active semiconductor region AA are initially intrinsic, whereby for the channel zone an intrinsic doping i results for the channel zone between source zone S and drain zone D with their respective n⁺-type doping. The diode doping zone DD is once again formed in a manner directly adjoining the source zone S with a p⁺-type doping, whereby a P/N diode results at the diode side area, i.e. at that side area of the third doping zone DD which is effective for the diode function. In order to improve an electrical conductivity of the doping zones and in particular for improved contact-connection of the source zone S, the drain zone D and the diode doping zone DD, a metal-semiconductor compound may be formed at the surface of the doping zones. Metal-semiconductor compounds of this type may be produced by saliciding or siliciding methods, wherein firstly a metallic material is deposited over the whole area and afterward a thermal treatment is effected in order to form a metal-semiconductor compound layer 8 or a silicide (when using silicon). Finally, the non-converted metallic material which has been formed for example only at the surface of the second insulating layer 4 is removed again, whereby the metal-semiconductor compound layer 8 illustrated in FIG. 2 can be formed.

In order to avoid a short-circuit between the diode doping zone DD and the source zone S or drain zone D, it is necessary, however, in accordance with FIG. 2, previously to form a blocking layer 7 at the surface of the doping zones S and DD in the surface region of the diode side area. To put it more precisely, the blocking layer 7, which may constitute an oxide layer, for example, prevents a surface contact-connection between the mutually adjoining doping zones S and DD. It goes without saying that it is possible once again to use opposite dopings or else non-intrinsic semiconductor materials. In the same way, the diode doping zone may once again also be formed in a manner directly adjoining the doping zone D.

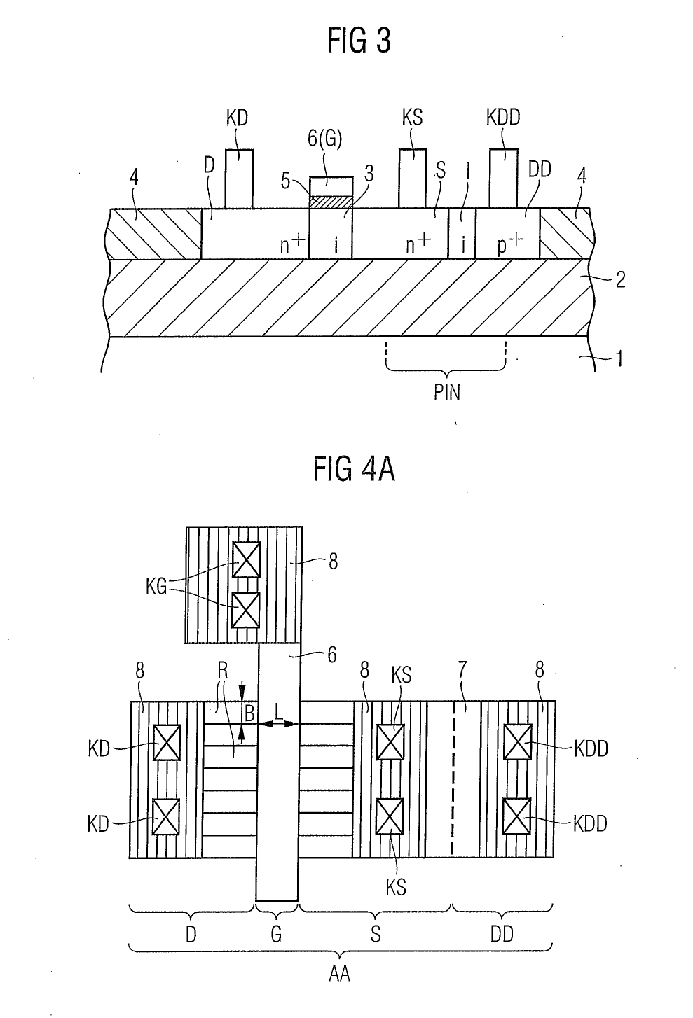

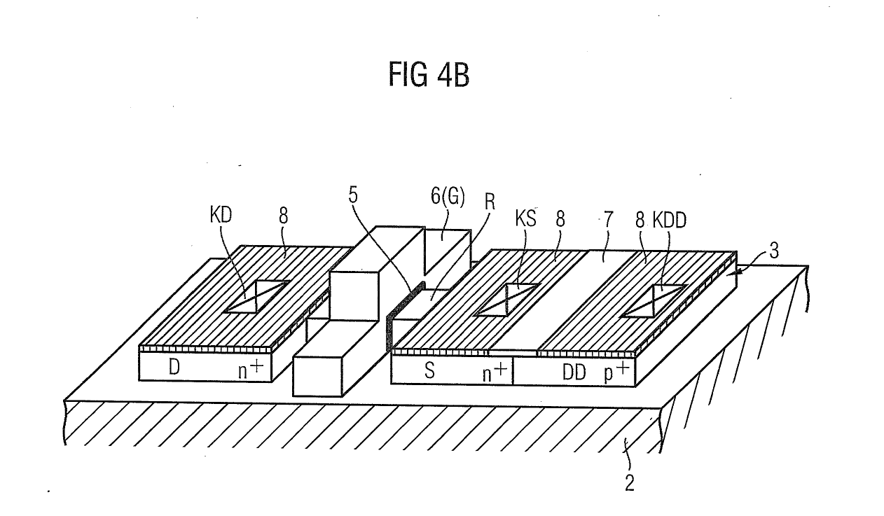

FIG. 3 illustrates a simplified sectional view of a semiconductor circuit arrangement in accordance with a third exemplary embodiment, wherein identical reference symbols designate elements identical or corresponding to those in FIGS. 1 and 2, for which reason a repeated description is dispensed with below.

In accordance with FIG. 3, it is also possible, then, to form a PiN diode as measuring diode MD in the active semiconductor region AA, wherein an intrinsic semiconductor material is firstly used as the thin semiconductor layer 3 and the diode doping zone DD is spaced apart from the source zone S or drain zone D an intrinsic semiconductor region BY. This results in the PiN diode illustrated in FIG. 3, which, particularly when connected up in the forward direction, leads to further improved measurement results and requires only a slightly increased space requirement. Owing to the low carrier density, the conductivity of the intrinsic semiconductor region I is very low. This zone can conduct well, however, if charge carriers pass from the adjoining more heavily doped doping zones S and DD into the intrinsic semiconductor region I. This is the case whenever a diode is forward-biased and the intrinsic semiconductor region I is sufficiently thin.

FIGS. 4A and 4B illustrate a simplified plan view and an associated perspective partial view of a semiconductor circuit arrangement in accordance with a fourth exemplary embodiment, wherein identical reference symbols designate elements identical or corresponding to those in FIGS. 1 to 3, for which reason a repeated description is dispensed with below.

In accordance with FIGS. 4A and 4B, then, the field effect transistor used is a multi-gate field effect transistor, in which the active semiconductor region AA has a multiplicity of fins R in particular in the region below the control layer 6 or the control electrode G, the fins being situated at the surface of the first insulating layer 2. In accordance with FIG. 4A, by way of example, the active semiconductor region AA is divided into four fins R running parallel to one another in the region below the control electrode G, over which fins the control electrode G runs in each case in a manner isolated only by the gate dielectric 5. Although the fins R are formed with essentially perpendicular side areas in accordance with this exemplary embodiment, it is also possible, in principle, to use fins having a different form. In particular, beveled side areas of the fins R which meet the surface of the insulating layer 2 at an angle of greater than 90° are also conceivable in this case.

In order to realize in particular the sub-45-nanometer field effect transistors mentioned in the introduction, it is accordingly possible to pattern the control electrode G with a width of less than 45 nanometers, which therefore defines the gate length L. With a gate length L of this type, a width B of the fins R would preferably lie in a region of approximately 30 nanometers. With such a ratio of gate length L to the thickness or width B of the fins R, it is possible to ensure a good electrostatic control over the channel zones. A height of the fins R which are formed perpendicular to the insulating layer 2, for example, may be 60 nanometers, for example.

Preferably, multi-gate field effect transistors having a multiplicity of control electrodes or gates G are accordingly used for realizing the field effect transistors. In particular, dual-gate FETs, triple-gate FETS or FinFETs shall be mentioned as realization possibilities in this case.

Although a metal-semiconductor compound layer 8 has been formed with the use of a blocking layer 7 at the surfaces of the doping zones S, D and DD in accordance with FIGS. 4A and 4B, this can also be omitted as in the exemplary embodiments in accordance with FIGS. 1 and 3. In the same way, it is also possible to use a thin intrinsic semiconductor layer 3 for the active semiconductor region 3 and/or for the diode doping zone DD to be spaced apart from the source zone S or drain zone D by an intrinsic semiconductor region I in accordance with FIG. 3 for the realization of a PiN diode.

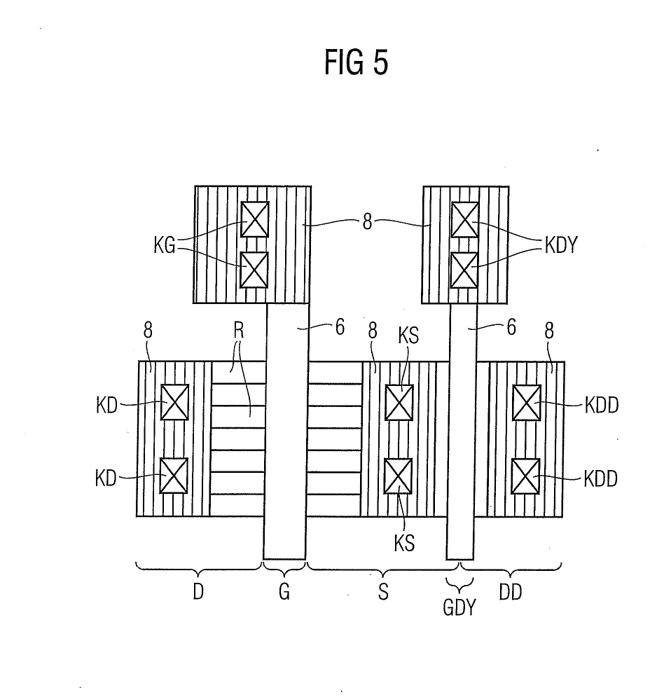

FIG. 5 illustrates a simplified plan view of a semiconductor circuit arrangement in accordance with a fifth exemplary embodiment, wherein identical reference symbols illustrate elements identical or corresponding to those in FIGS. 1 to 4, for which reason a repeated description is dispensed with below.

For further simplification of a production method and in particular for reducing costs, as an alternative to the formation of the blocking layer 7 illustrated in FIGS. 2 and 4, it is also possible to form a dummy gate dielectric with an overlying dummy control electrode GDY. Accordingly, in accordance with FIG. 5, at the same time as the patterning of the gate dielectric 5 and the control layer 6 for the control electrode G, an electrically inactive dummy control electrode GDY is formed, which once again at the surface of the doping zones in the region of the diode side area prevents a deposition of metallic material and hence a reaction with an underlying semiconductor material, thereby reliably preventing a short circuit between e.g., the source zone S and the diode doping zone DD.

Since gate masks of this type first of all have a very high accuracy and moreover are present anyway, the production costs for a semiconductor circuit arrangement of this type can be reduced further. The dummy control electrode GDY preferably has a connection region with at least one dummy contact KDY, which can be electrically connected to the source zone S for example via a source contact KS. An undesirable parasitic circuit element can be reliably prevented in this way.

In principle, however, the dummy control electrode GDY could also be realized such that it is not connected up or is at floating potential, or could be connected to a contact KDD of the diode doping zone DD.

In the same way, it is also possible to realize a transistor structure as in FIG. 1 or 3, that is to say without the use of a multiplicity of fins R. Furthermore, the measuring diode MD to be realized may constitute a P/N diode in accordance with FIG. 2 or a PiN diode in accordance with FIG. 3. Moreover, the field effect transistor may once again be an NMOS or PMOS field effect transistor.

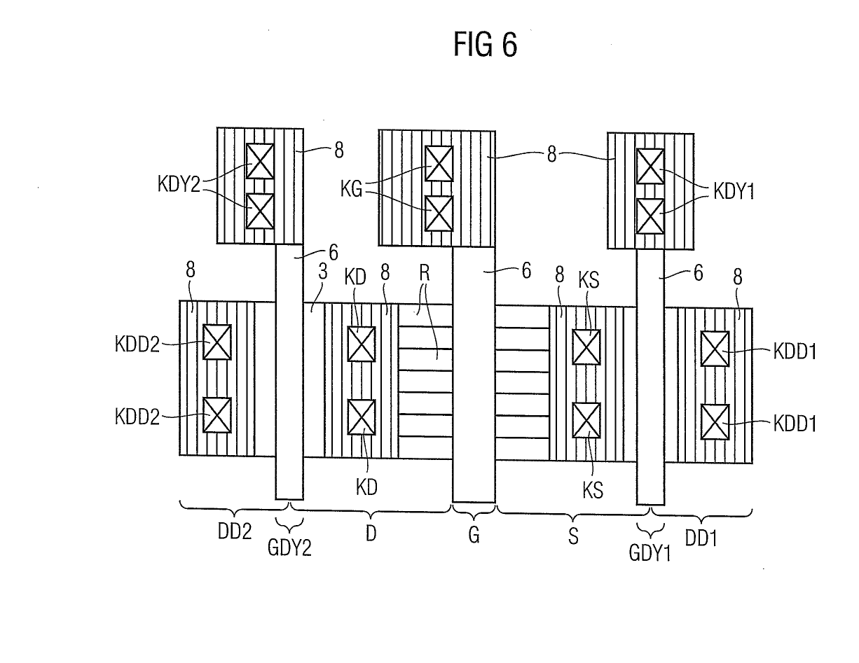

FIG. 6 illustrates a simplified plan view of a semiconductor circuit arrangement in accordance with a sixth exemplary embodiment, wherein identical reference symbols illustrate elements identical or corresponding to those in FIGS. 1 to 5, for which reason a repeated description is dispensed with below.

In accordance with FIG. 6, the semiconductor circuit arrangement can have not just one measuring diode MD, formed with the source zone S for example, but a total of two measuring diodes realized by the third doping zone DD1 and a fourth doping zone DD2. To put it more precisely, in addition to the exemplary embodiment already illustrated in FIG. 5, on the drain side as well a measuring diode is realized by a further diode doping zone DD2 together with the drain zone D, whereby a further measuring diode can be operated once again in the forward direction.

Once again it is possible to form a further dummy control electrode GDY2 in the surface region of the further diode side area, i.e. at the surface of the doping zones D and DD2, in order to prevent a short circuit of the highly conductive metal-semiconductor compound layers 8 or of the drain zone D with the connection zone of the further measuring diode.

As in FIG. 5, a further contact KDY2 of the further dummy control electrode GDY2 may once again be electrically connected to a contact KDD2 of the further diode doping zone DD2. It goes without saying that the arrangement in accordance with FIG. 6 can also be combined with any one of the exemplary embodiments mentioned above, in which case the metal-semiconductor compound layer 8 may be omitted, a P/N diode or PiN diode, etc. is used.

A semiconductor circuit arrangement and an associated method for temperature detection are obtained in this way, wherein a temperature T of field effect transistors can be detected highly accurately and very cost-effectively on the basis of a measured voltage U_{MD} with minimal space requirement. In the event of a deviation of the temperature, corresponding measures realized in respect of circuitry can be implemented, such as e.g., an adaptation of the supply voltage Vₛₛ in the respective circuit sections or matching of the temperature by local heating of the circuit sections or components.

The invention has been described above on the basis of an SOI semiconductor substrate with a thin silicon semiconductor layer. However, it is not restricted thereto and also encompasses alternative carrier substrates in the same way.

Furthermore, the invention has been described for an NMOS transistor, the measuring diode having a p-doped zone as anode. In the same way, it is also possible to realize a PMOS transistor, the measuring diode being connected oppositely and having an n-doped zone as cathode.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor circuit arrangement comprising:
a semiconductor substrate;
a first insulating layer, which is formed on the semiconductor substrate; and
an active semiconductor region, formed on the first insulating layer and laterally delimited by a second insulating layer;
wherein, in the active semiconductor region, a first and second doping zone of a first conduction type are formed as far as the surface of the first insulating layer for the definition of at least one channel zone, and there is formed at the surface of the at least one channel zone at least one gate dielectric and thereon a control electrode for the realization of a field effect transistor, wherein; and
wherein, in the active semiconductor region, at least one diode doping zone of a second conduction type, which is opposite to the first conduction type, is furthermore formed as far as the surface of the first insulating layer, which zone realizes at least one measuring diode via a diode side area with the first or second doping zone of the field effect transistor and is delimited by the second insulating layer at its further side areas.

2. The semiconductor circuit arrangement as claimed in claim 1, wherein the first or second doping zone of the field effect transistor directly adjoins the at least one diode doping zone for the realization of at least one P/N diode.

3. The semiconductor circuit arrangement as claimed in claim 1, wherein the first or second doping zone of the field effect transistor is spaced apart from the at least one diode doping zone by an intrinsic semiconductor region for the realization of at least one PiN diode.

4. The semiconductor circuit arrangement as claimed in claim 1, wherein the field effect transistor constitutes a multi-gate field effect transistor having a multiplicity of fins in the region of the control electrode, wherein the fins are laterally delimited by the second insulating layer.

5. The semiconductor circuit arrangement as claimed in claim 1, wherein, at the surface of the doping zones, a blocking layer is formed in the region of the diode side area and a metal-semiconductor compound layer is formed in the remaining region not covered by the gate dielectric.

6. The semiconductor circuit arrangement as claimed in claim 1, wherein, at the surface of the doping zones, a dummy gate dielectric with an overlying dummy control electrode is formed in the region of the diode side area and a metal-semiconductor compound layer is formed in the remaining region not covered by the gate dielectric with the overlying control electrode.

7. The semiconductor circuit arrangement as claimed in claim 1, wherein the control electrode has a metallic material having a work function in the middle of the band gap of the semiconductor material of the active semiconductor region.

8. The semiconductor circuit arrangement as claimed in claim 1, wherein a width of the fins is significantly less than a gate length of the control electrode.

9. The semiconductor circuit arrangement as claimed in claim 1, wherein the second insulating layer constitutes an STI layer.

10. The semiconductor circuit arrangement as claimed in claim 1, wherein it constitutes a part of a temperature-compensated analog circuit.

11. A method for temperature detection in a semiconductor circuit, the method comprising:
providing a semiconductor substrate;
providing a first insulating layer on the semiconductor substrate;
providing an active semiconductor region on the first insulating layer that is laterally bounded by a second insulating layer;
providing a first and second doping zones of a first conduction type on the first insulating layer and in the active semiconductor region;
providing at least one channel zone bounded by the first and second doping zones;
providing at least one gate dielectric on the surface of the at least one channel zone;
providing a control electrode on the at least one gate dielectric;
providing at least one diode doping zone of a second conduction type, which is opposite to the first conduction type, on the surface of the first insulating layer and in the active semiconductor region;
impressing a diode measuring current in the forward direction on a measuring diode, and
measuring a diode voltage dropped across the measuring diode.

12. The method as claimed in claim 11, wherein the measured diode voltage is compared with a reference voltage.

13. The method as claimed in claim 11, wherein the temperature T to be measured is estimated from the equation:
UMD=0.5 V−T×1.8 mV/K
where UMD represents the measured diode voltage.

14. The method as claimed in claim, wherein the diode measuring current is less than 1/100 of the drain current of the field effect transistor.

15. A semiconductor circuit comprising:
a semiconductor substrate;
a first insulating layer on the semiconductor substrate;
an active semiconductor region on the first insulating layer that is laterally bounded by a second insulating layer;
a first and second doping zones of a first conduction type on the first insulating layer and in the active semiconductor region;
at least one channel zone bounded by the first and second doping zones;
at least one gate dielectric on the surface of the at least one channel zone;
a control electrode on the at least one gate dielectric;
at least one diode doping zone of a second conduction type, which is opposite to the first conduction type, on the surface of the first insulating layer and in the active semiconductor region,
means for temperature detection via a voltage drop relative to the at least one diode doping zone.

16. The semiconductor circuit of claim 15, further comprising at least one measuring diode via a diode side area with the first or second doping zone that is bounded by the second insulating layer at its further side areas.

17. The semiconductor circuit of claim 15, wherein the first or second doping zone directly adjoins the at least one diode doping zone thereby forming at least one P/N diode.

18. The semiconductor circuit of claim 15, wherein the first or second doping zone is spaced apart from the at least one diode doping zone by an intrinsic semiconductor region thereby forming at least one PiN diode.

19. The semiconductor circuit of claim 15, wherein the at least one channel zone bounded by the first and second doping zones forms a field effect transistor.

20. The semiconductor circuit of claim 19, wherein the field effect transistor constitutes a multi-gate field effect transistor having a multiplicity of fins in the region of the control electrode, wherein the fins are laterally delimited by the second insulating layer.
